(19) United States
(12) Patent Application Publication
(10) Pub. No.: US 2026/0026147 A1
(43) Pub. Date: Jan. 22, 2026

(54) APPARATUS FOR MANUFACTURING DISPLAY DEVICE

(71) Applicant: Samsung Display Co., LTD., Yongin-si (KR)

(72) Inventor: Jeong Won HAN, Yongin-si (KR)

(21) Appl. No.: 19/030,627

(22) Filed: Jan. 17, 2025

(30) Foreign Application Priority Data
Jul. 22, 2024 (KR) 10-2024-0096472

(51) Int. Cl. H10H 29/03; H01L 25/075

(52) U.S. Cl. CPC H10H 29/03; H01L 25/0753

(57) ABSTRACT

An apparatus for manufacturing a display device includes a stamp member including an adsorption area and first to fourth edge areas, a stamp head unit which adsorbs the adsorption area of the stamp member, a main body unit which has the stamp head unit installed therein and is movable along a first direction and a second direction, a clamping unit installed in the main body unit to be movable along the first direction and the second direction, and a pressurizing unit installed in the main body unit to be movable along the first direction and the second direction, where the pressurizing unit operates in one of a first mode and a second mode, and the clamping unit includes first to fourth clampers which clamp the first to fourth edge areas of the stamp member, respectively, when the pressurizing unit is changed from the second mode to the first mode.

This application claims priority to Korean Patent Application No. 10-2024-0096472, filed on Jul. 22, 2024, and all the benefits accruing therefrom under 35 U.S.C. § 119, the content of which in its entirety is herein incorporated by reference.

### BACKGROUND

### (1) Field

The disclosure generally relates to an apparatus for manufacturing a display device.

### (2) Description of the Related Art

Display devices have become an important element of electronic devices to display information to a user. A display device may include a light emitting element as a light source. The light emitting element may be transferred in various manners on a substrate for manufacturing the display device.

For example, the light emitting element may be transferred onto a backplane of the display device, using a stamp film including at least one layer. The stamp film may be attached to the light emitting element, using adhesion defined at a portion of the stamp film, and the light emitting element adhered on the stamp film may be moved on the backplane.

### SUMMARY

An embodiment of apparatus for manufacturing a display device includes a stamp member including an adsorption area and first to fourth edge areas surrounding the adsorption area in different directions, a stamp head unit which adsorbs the adsorption area of the stamp member, a main body unit including the stamp head unit installed therein, where the main body unit is movable along a first direction facing the stamp member and a second direction as the opposite direction of the first direction, a clamping unit installed in the main body unit to be movable along the first direction and the second direction, and a pressurizing unit installed in the main body unit to be movable along the first direction and the second direction, where the pressurizing unit operates in one of a first mode, in which the clamping unit is not pressurized, and a second mode, in which the clamping unit is pressurized in the first direction, where the clamping unit comprising first to fourth clampers which clamp the first to fourth edge areas of the stamp member, respectively, when the pressurizing unit is changed from the second mode to the first mode.

In an embodiment, each of the first to fourth edge areas may include a first non-adsorption area relatively adjacent to the adsorption area, and a second non-adsorption area relatively more distant from the adsorption area than the first non-adsorption area. In such an embodiment, a width of the first non-adsorption area may gradually decrease along a direction distant from the adsorption area. In such an embodiment, a width of the second non-adsorption area may be constant along the direction distant from the adsorption area.

In an embodiment, the width of the second non-adsorption area may be smaller than a width of the adsorption area.

In an embodiment, a width of each of the first to fourth edge areas may gradually decrease along a direction distant from the adsorption area.

In an embodiment, each of the first to fourth clampers may include a first clamping body installed in the main body unit to be slidable along the first direction and the second direction, a rotating shaft installed in the first clamping body to be rotatable with respect to a third direction intersecting the first direction, a second clamping body installed at the rotating shaft to rotatably move with respect to the rotating shaft to be position in a clamping posture, at which the stamp member is clamped, or an open posture, at which the stamp member is not clamped, and a first elastic member installed between the rotating shaft and the second clamping body, to apply, to the second clamping body, a force with which the second clamping body is adhered closely to the first clamping body.

In an embodiment, the main body unit may include a stopper which limits a movement of the clamping unit in the first direction when the pressurizing unit operates in the second mode. In such an embodiment, the second clamping body may include a guide member extending in a radius direction of the rotating shaft. In such an embodiment, the guide member may be linearly moved in the first direction by a force applied by the pressurizing unit before the clamping unit is in contact with the stopper when the pressurizing unit operates in the second mode, and be rotatably moved with respect to the rotating shaft by a force applied by the pressurizing unit after the clamping unit is in contact with the stopper.

In an embodiment, the first clamping body may include a first inclined surface on which one surface of a corresponding one of the first to fourth edge areas of the stamp member is settled. In such an embodiment, the second clamping body may include a second inclined surface on which an opposite surface of the corresponding one of the first to fourth edge areas of the stamp member is settled. In such an embodiment, the clamping posture of the second clamping body may be a posture at which the first inclined surface and the second inclined surface are relatively adjacent to each other as the guide member linearly moves. In such an embodiment, the open posture of the second clamping body may be a posture at which the first inclined surface and the second inclined surface are relatively spaced apart from each other as the guide member rotatably moves.

In an embodiment, a plurality of bumps which fixes the opposite surface may be defined on the second inclined surface.

In an embodiment, the first elastic member may include a torsional spring.

In an embodiment, the apparatus may further include a stage spaced apart from the stamp head unit in the first direction, to support at least a portion of the first to fourth edge areas. In such an embodiment, the stage may include a groove portion recessed from an upper surface thereof in the first direction. In such an embodiment, the groove portion may accommodate the adsorption area of the stamp member when the pressurizing unit operates in the second mode.

In an embodiment, when a mode of the pressurizing unit is changed from the first mode to the second mode, the stamp head unit may allow the stamp member to enter into the groove portion in a state in which the adsorption area of the stamp member is adsorbed by a force with which the main body unit moves in the first direction.

In an embodiment, each of the first to fourth edge areas may include a pressing area adjacent to the adsorption area and a clamping area except the pressing area. In such an embodiment, the clamping unit may include: a pressing member extending in the first direction, a guide groove including the pressing member installed therein, and a second elastic member installed in the guide groove. In such an embodiment, the pressing member may pressurize the pressing area when the pressurizing unit operates in the second mode.

In an embodiment, when the pressurizing unit operates in the second mode, the pressing member may be moved in the first direction by a force with which the pressurizing unit pressurizes the clamping unit after the stamp member is in contact with a bottom surface of the groove portion such that the pressing area is pressurized by the pressing member, the second elastic member may be compressed in the second direction by a force with which the pressing member pressurizes the pressing area, to apply a restoring force to the pressing member in the first direction, and the clamping area of the stamp member may receive a repulsive force in the second direction while being in contact with a corner of the groove portion, to be bent.

In an embodiment, when a mode of the pressurizing unit is changed from the second mode to the first mode, the adsorption area of the stamp member may be in contact with the stamp head unit, the pressing area of the stamp member may be in contact with the pressing member, and the clamping area of the stamp member may be in contact with the clamping unit.

In an embodiment, after the mode of the pressurizing unit is changed from the second mode to the first mode, a degree to which any one of the clamping areas is bent with respect to the adsorption area may be greater than a degree to which a corresponding one of the pressing areas is bent with respect to the adsorption area.

In an embodiment, a position at which the adsorption area and the stamp head unit are in contact with each other may be closer to the stage than a position at which one of the pressing areas is in contact with the pressing member.

In an embodiment, the second elastic member may include a compression spring.

In an embodiment, the apparatus may further include a third elastic member connected between the main body unit and the clamping unit. In such an embodiment, the third elastic member may be extended when the pressurizing unit operates in the second mode, to apply a restoring force to the clamping unit in the second direction.

In an embodiment, when the mode of the pressurizing unit is changed from the first mode to the second mode, the clamping unit may be moved in the first direction by a force with which the pressurizing unit pressurizes the clamping unit. In such an embodiment, when the mode of the pressurizing unit is changed from the second mode to the first mode, the clamping unit may be moved in the second direction by the restoring force in a state in which the clamping unit clamps the first to fourth edge areas of the stamp member, such that a tensile force is applied to the adsorption area of the stamp member in different directions.

In an embodiment, the third elastic member may include an extension spring.

### BRIEF DESCRIPTION OF THE DRAWINGS

The above and other features of embodiments of the disclosure will become more apparent by describing in further detail embodiments thereof with reference to the accompanying drawings.

FIG. 1 is a plan view illustrating a display device manufactured by an apparatus for manufacturing a display device in accordance with embodiments of the disclosure.

FIG. 2 is a plan view illustrating an embodiment of any one of pixels shown in FIG. 1.

FIG. 3 is a sectional view illustrating an embodiment of the display device shown in FIG. 1.

FIG. 4 is a conceptual view illustrating an embodiment of an apparatus for manufacturing a display device.

FIG. 5A is a plan view illustrating an embodiment of a stamp member of the apparatus shown in FIG. 4.

FIG. 5B is a plan view illustrating an embodiment of the stamp member shown in FIG. 5A.

FIG. 6A is a plan view illustrating an embodiment of a clamping unit of the apparatus shown in FIG. 4.

FIG. 6B is a side view of a first clamper shown in FIG. 6A.

FIG. 6C is a rear view of the first clamper shown in FIG. 6A.

FIG. 6D is a front view of the first clamper shown in FIG. 6A.

FIG. 7 is a conceptual view schematically illustrating a state in which the clamping unit of the apparatus shown in FIG. 4 extends the stamp member.

FIGS. 8A to 8F are conceptual views schematically illustrating operation stages in which the apparatus clamps and extends the stamp member in accordance with an embodiment of the disclosure.

FIGS. 9A to 9C are conceptual views schematically illustrating a process of transferring light emitting elements disposed on an intermediary member onto a stamp member.

FIGS. 10A to 10F are conceptual views schematically illustrating operation stages in which the apparatus transfers light emitting elements onto a pixel circuit layer on a circuit board in accordance with an embodiment of the disclosure.

FIG. 11 is a block diagram illustrating an embodiment of a display system.

FIGS. 12 to 15 are perspective views illustrating application examples of the display system shown in FIG. 11.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. It will be also understood that when an element is referred to as being “between” two elements, it can be the only element between the two elements, or one or more intervening elements may also be present therebetween. In the disclosure, when an element is referred to as being “connected” or “coupled” to another element, it can be directly connected or coupled to the another element or be indirectly connected or coupled to the another element with one or more intervening elements interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from X, Y, and Z” can be construed as X only, Y only, Z only, or any combination of two or more items X, Y, and Z (e.g., XYZ, XYY, YZ, ZZ).

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The disclosure generally relates to an apparatus for manufacturing a display device. Hereinafter, an apparatus for manufacturing a display device in accordance with an embodiment of the disclosure will be described with reference to the accompanying drawings.

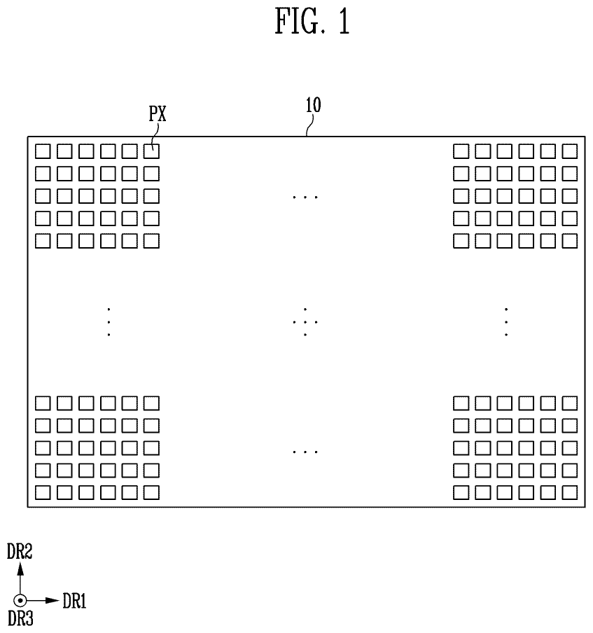

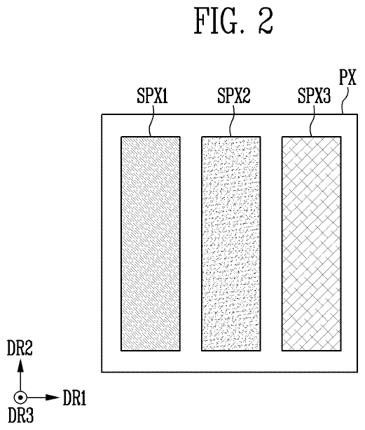

FIG. 1 is a plan view illustrating a display device manufactured by an apparatus for manufacturing a display device in accordance with embodiments of the disclosure. FIG. 2 is a plan view illustrating an embodiment of any one of pixels shown in FIG. 1.

Referring to FIG. 1, an embodiment of the display device 10 may be configured to output optical information. In an embodiment, for example, the display device 10 is a device which displays a moving image or a still image, and may be used as a display screen of not only portable electronic devices such as a mobile phone, a smart phone, a tablet personal computer (PC), a mobile communication terminal, an electronic notebook, an electronic book, a portable multimedia player (PMP), a navigation system, and an ultra-mobile PC, but also various products such as a television, a notebook computer, a monitor, an advertisement board, and Internet of things (IoT).

In an embodiment, as shown in FIG. 1, the display device 10 may be formed in a rectangular plane having long sides in a first direction DR1 and short sides in a second direction DR2 intersecting the first direction DR1 in a plan view or when viewed in a third direction DR3. The third direction DR3 may be a direction perpendicular to the first direction DR1 and the second direction DR2 or a thickness direction of the display device 10. A corner at which the long side in the first direction DR1 and the short side in the second direction DR2 meet each other may be formed round to have a predetermined curvature or be formed at a right angle.

The planar shape of the display device 10 is not limited to a quadrangular shape, and the display device 10 may be formed in another polygonal shape, a circular shape, or an elliptical shape. The display device 10 may be formed flat, but the disclosure is not limited thereto. In an embodiment, for example, the display device 10 may include a curved portion which is formed at a left/right end and has a constant curvature or a changing curvature. In addition, the display device 10 may be formed flexible enough to be warpable, curvable, bendable, foldable or rollable.

The display device 10 may further include pixels PX for displaying an image, scan lines (not shown) extending in the first direction DR1, and data lines (not shown) extending in the second direction DR2. The pixels PX may be arranged in a matrix form in the first direction DR1 and the second direction DR2.

Each of the pixels PX may include a plurality of sub-pixels SPX1, SPX2, and SPX3 as shown in FIG. 2. In an embodiment, as shown in FIG. 2, each of the pixels PX may include three sub-pixels SPX1, SPX2, and SPX3, i.e., a first sub-pixel SPX1, a second sub-pixel SPX2, and a third sub-pixel SPX3. However, embodiments are not limited thereto.

The first sub-pixel SPX1, the second sub-pixel SPX2, and the third sub-pixel SPX3 may be connected to any one data line among the data lines and at least one scan line among the scan lines.

Each of the first sub-pixel SPX1, the second sub-pixel SPX2, and the third sub-pixel SPX3 may have a rectangular, square or rhombic planar shape. In an embodiment, for example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 2. Alternatively, in some embodiments, each of the first sub-pixel SPX1, the second sub-pixel SPX2, and the third sub-pixel SPX3 may have a square or rhombic planar shape including sides having the same length in the first direction DR1 and the second direction DR2.

In an embodiment, as shown in FIG. 2, the first sub-pixel SPX1, the second sub-pixel SPX2, and the third sub-pixel SPX3 may be arranged in the first direction DR1. Alternatively, one of the second sub-pixel SPX2 and the third sub-pixel SPX3 and the first sub-pixel SPX1 may be arranged in the first direction DR1, and the other of the second sub-pixel SPX2 and the third sub-pixel SPX3 and the first sub-pixel SPX1 may be arranged in the second direction DR2.

Alternatively, one of the first sub-pixel SPX1 and the third sub-pixel SPX3 and the second sub-pixel SPX2 may be arranged in the first direction DR1, and the other of the first sub-pixel SPX1 and the third sub-pixel SPX3 and the second sub-pixel SPX2 may be arranged in the second direction DR2. Alternatively, one of the first sub-pixel SPX1 and the second sub-pixel SPX2 and the third sub-pixel SPX3 may be arranged in the first direction DR1, and the other of the first sub-pixel SPX1 and the second sub-pixel SPX2 and the third sub-pixel SPX3 may be arranged in the second direction DR2.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm. However, embodiments are not limited thereto.

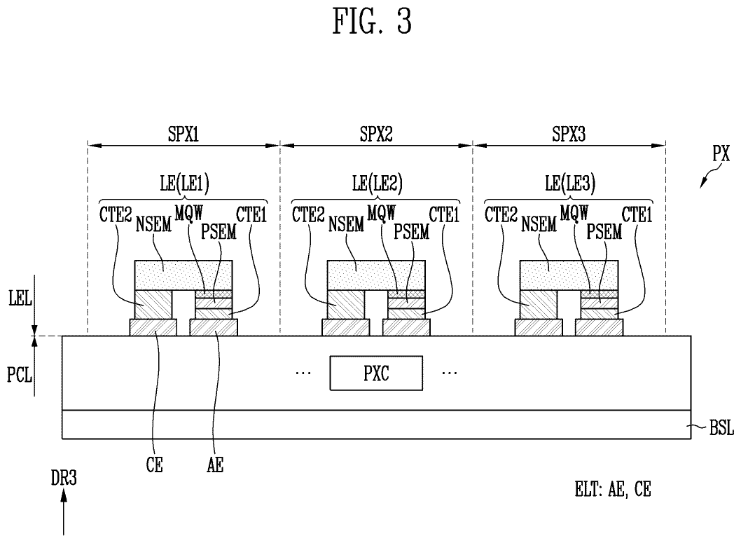

Each of the first sub-pixel SPX1, the second sub-pixel SPX2, and the third sub-pixel SPX3 may include an inorganic light emitting element including an inorganic semiconductor as a light emitting element LE (see FIG. 3) emitting light.

In some embodiments, the light emitting element LE may have various shapes. In an embodiment, for example, the light emitting element LE may be a flip chip type micro light emitting diode (LED). Alternatively, the light emitting element LE may be a lateral type micro LED. Alternatively, the light emitting element LE may be a vertical type micro LED. However, the embodiment of the disclosure is not limited to a specific example.

In an embodiment, as shown in FIG. 2, an area of the first sub-pixel SPX1, an area of the second sub-pixel SPX2, and an area of the third sub-pixel SPX3 may be substantially the same as each other, but embodiments are not limited thereto. In another embodiment, for example, one of the area of the first sub-pixel SPX1, the area of the second sub-pixel SPX2, and the area of the third sub-pixel SPX3 may be different from another of the area of the first sub-pixel SPX1, the area of the second sub-pixel SPX2, and the area of the third sub-pixel SPX3. Alternatively, two of the area of the first sub-pixel SPX1, the area of the second sub-pixel SPX2, and the area of the third sub-pixel SPX3 may be substantially the same as each other, and the remaining one of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. Alternatively, the area of the first sub-pixel SPX1, the area of the second sub-pixel SPX2, and the area of the third sub-pixel SPX3 may be different from one another.

FIG. 3 is a sectional view illustrating an embodiment of the display device shown in FIG. 1.

Referring to FIG. 3, one pixel PX of the display device 10 may include or be configured with a pixel circuit layer PCL and a light emitting element layer LEL.

The pixel circuit layer PCL may be a layer including pixel circuits PXC for driving light emitting elements LE. In an embodiment, for example, the pixel circuit layer PCL may be a backplane layer. The pixel circuit layer PCL may include a base layer BSL, metal layers for forming the pixel circuits PXC, and insulating layers disposed between the metal layers.

In embodiments, the base layer BSL may be a base substrate or a base member, which is used to support the display device 10. The base layer BSL may be a rigid substrate made of a glass material. The base layer BSL may include a silicon material. The base layer BSL may be a flexible substrate which is bendable, foldable, rollable, and the like. The base layer BSL may include an insulating material including polymer resin such as polyimide.

In some embodiments, each of the pixel circuits PXC may include a transistor. In an embodiment, for example, each of the pixel circuits PXC may include a thin film transistor. Also, each of the pixel circuits PXC may further include a storage capacitor. The pixel circuits PXC may be electrically connected to the light emitting elements LE, to provide an electrical signal for allowing the light emitting elements LE to emit light.

The light emitting element layer LEL may be disposed on the pixel circuit layer PCL. The light emitting element layer LEL may include an electrode layer ELT and the light emitting elements LE. The electrode layer ELT may include pixel electrodes AE and common electrodes CE. Each of a first sub-pixel SPX1, a second sub-pixel SPX2, and a third sub-pixel SPX3 may include a light emitting element LE connected to a pixel electrode AE and a common electrode CE.

In some embodiments, the light emitting elements LE may include a first light emitting element LE1 included in the first sub-pixel SPX1, which is configured to emit light of a first color, a second light emitting element LE2 included in the second sub-pixel SPX2, which is configured to emit light of a second color, and a third light emitting element LE3 included in the third sub-pixel SPX3, which is configured to emit light of a third color. The pixel electrode AE may be designated as an anode electrode, and the common electrode CE may be designated as a cathode electrode.

The pixel electrodes AE and the common electrodes CE may be disposed on the pixel circuit layer PCL.

Each of the pixel electrodes AE may be electrically connected to the pixel circuit PXC of the pixel circuit layer PCL. Accordingly, a pixel voltage or an anode voltage, which is controlled by the pixel circuit PXC (e.g., the transistor), may be applied to the pixel electrode AE.

Each of the common electrodes CE may be electrically connected to a power line formed in the pixel circuit layer PCL. Accordingly, a power voltage of the power line may be applied to the common electrodes CE.

The pixel electrodes AE and the common electrode CE may include a metal material having a high reflectivity, such as a stacked structure (Ti/Al/Ti) of aluminum and titanium, a stacked structure (ITO/AI/ITO) of aluminum and ITO, an APC alloy, or a stacked structure (ITO/APC/ITO) of an APC alloy and ITO. The APC alloy may be an alloy of silver (Ag), palladium (Pd), and copper (Cu). However, embodiments are not limited thereto.

In an embodiment, as shown in FIG. 3, each of the light emitting elements LE may be a flip chip type micro LED in which a first contact electrode CTE1 and a second contact electrode CTE2 are disposed such that the pixel electrode AE and the common electrode CE face each other. However, the shape of the light emitting element LE is not necessarily limited thereto.

The light emitting element LE may include an inorganic material (e.g., GaN). Each of a length of the light emitting element LE in the first direction DR1, a length of the light emitting element LE in the second direction DR2, and a length of the light emitting element LE in a third direction DR3 may be a few to hundreds of micrometers (μm). In an embodiment, for example, each of the length of the light emitting element LE in the first direction DR1, the length of the light emitting element LE in the second direction DR2, and the length of the light emitting element LE in the third direction DR3 may be about 100 μm or less. However, embodiments are not necessarily limited thereto.

Each of the light emitting elements LE may be a light emitting structure including an n-type semiconductor NSEM, an active layer MQW, a p-type semiconductor PSEM, the first contact electrode CTE1, and the second electrode CTE2.

A portion of the n-type semiconductor NSEM may be disposed on the active layer MQW. A portion of the n-type semiconductor NSEM may be disposed on the second contact electrode CTE2. In embodiments, one surface of the n-type semiconductor NSEM may face a display surface. The n-type semiconductor NSEM may be made of GaN doped with an n-type conductivity type dopant such as Si, Ge or Sn.

The active layer MQW may be disposed on a portion of one surface of the n-type semiconductor NSEM. The active layer MQW may be interposed between the n-type semiconductor NSEM and the p-type semiconductor PSEM. The active layer MQW may include a material including a single or multiple quantum well structure. In an embodiment where the active layer MQW includes the material including the multiple quantum well structure, the active layer MQW may have a structure in which a plurality of well layers and a plurality of barrier layers are alternately stacked. The well layer may be formed of InGaN, and the barrier layer may be formed of GaN or AlGaN. However, the disclosure is not limited thereto. Alternatively, the active layer MQW may have a structure in which a semiconductor material having a high band gap energy and a semiconductor material having a low band gap energy are alternately stacked. The active layer MQW may include different Group III to V semiconductor materials according to a wavelength range of emitted light.

The p-type semiconductor PSEM may be disposed on one surface of the active layer MQW. The p-type semiconductor PSEM may include or be made of GaN doped with a p-type conductivity type dopant such as Mg, Zn, Ca, Se or Ba.

The first contact electrode CTE1 may be disposed on the p-type semiconductor PSEM, and the second contact electrode CTE2 may be disposed on another portion of the one surface of the n-type semiconductor NSEM. The another portion of the one surface of the n-type semiconductor NSEM, on which the second contact electrode CTE2 is disposed, may be disposed distant from the portion of the one surface of the n-type semiconductor NSEM, on which the active layer MQW is disposed.

The first and second contact electrodes CTE1 and CTE2 and the electrode layer ELT may be adhered to each other, using various methods. In an embodiment, for example, the first and second contact electrodes CTE1 and CTE2 and the electrode layer ELT may be adhered to each other through a conductive adhesive member such as an anisotropic conductive film (ACF) or an anisotropic conductive paste (ACP). The first and second contact electrodes CTE1 and CTE2 and the electrode layer ELT may be adhered to each other through a laser bonding process or a thermo-compression bonding process. The first and second contact electrodes CTE1 and CTE2 and the electrode layer ELT may be adhered to each other through a soldering process. The first and second contact electrodes CTE1 and CTE2 and the electrode layer ELT may be adhered to each other through a eutectic bonding process.

In some embodiments, when the light emitting element LE is a flip chip type micro LED or a lateral type micro LED, a bump layer may be disposed on the electrode layer ELT, and the light emitting element LE may be attached to the electrode layer ELT through a laser bonding process or a thermo-compression bonding process. Alternatively, in some embodiments, when the light emitting element LE is a vertical type micro LED, a low melting point material layer having a relatively low melting point may be disposed on the electrode layer ELT, and the light emitting element LE may be attached to the electrode layer ELT through a eutectic bonding process. However, in the disclosure, the process of transferring the light emitting element LE is not particularly limited.

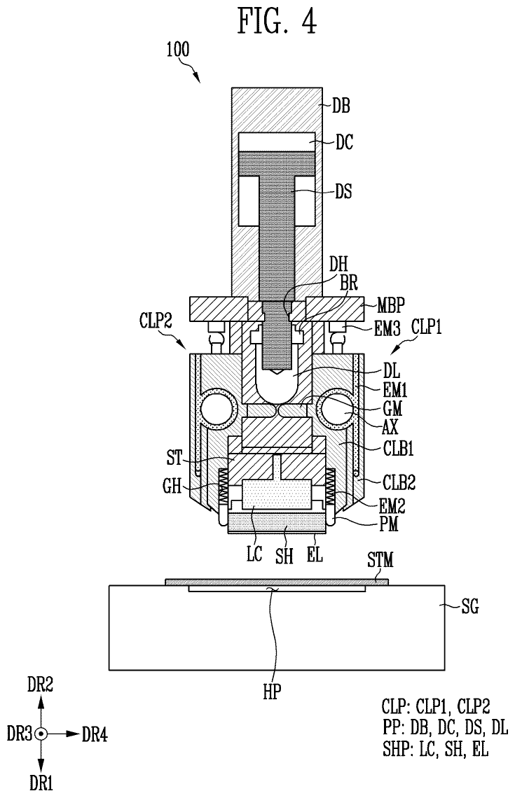

Hereinafter, an embodiment of an apparatus 100 for manufacturing the display device 10 described with reference to FIG. 1 will be described with reference to FIGS. 4, 5A, 5B, 6A to 6D, and 7. In FIGS. 4 to 7, any repetitive detailed descriptions of with the same or like elements as those described above will be simplified or omitted.

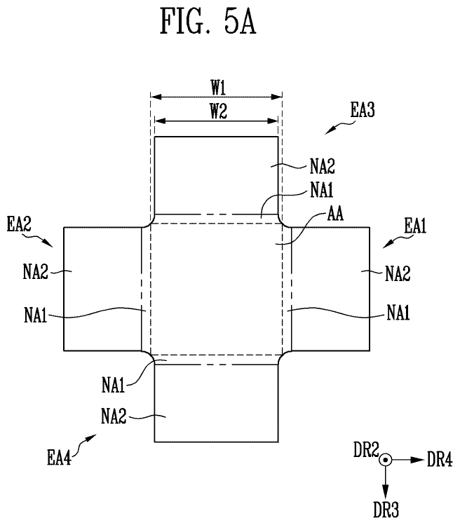

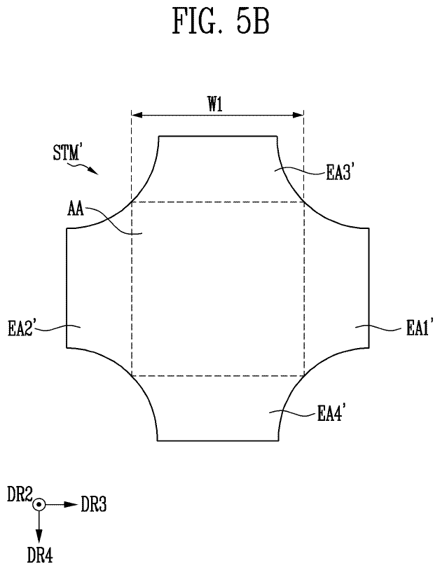

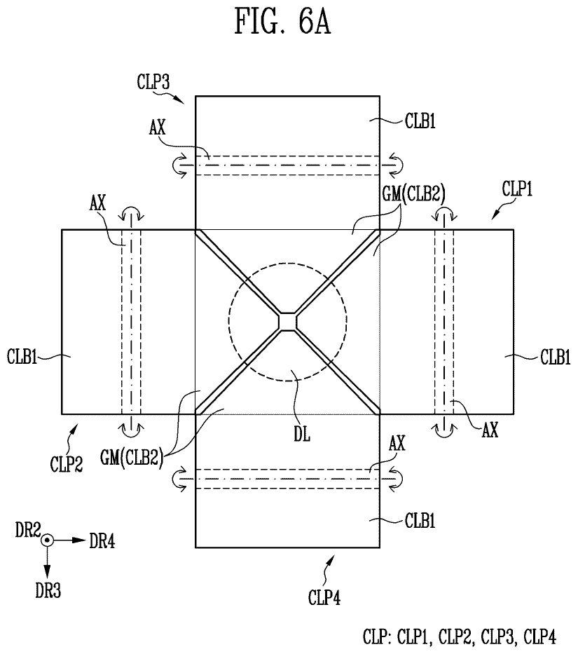

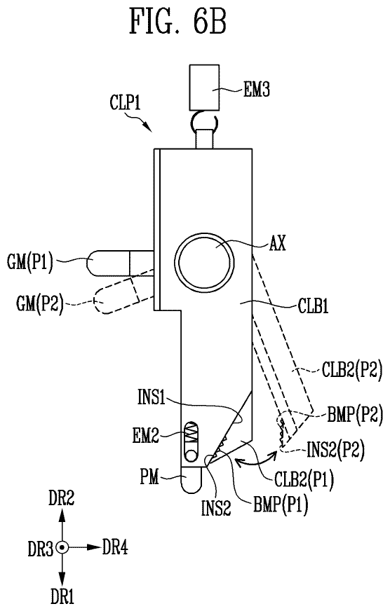

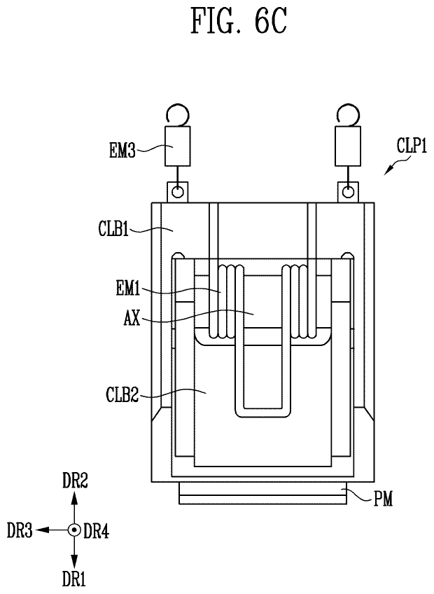

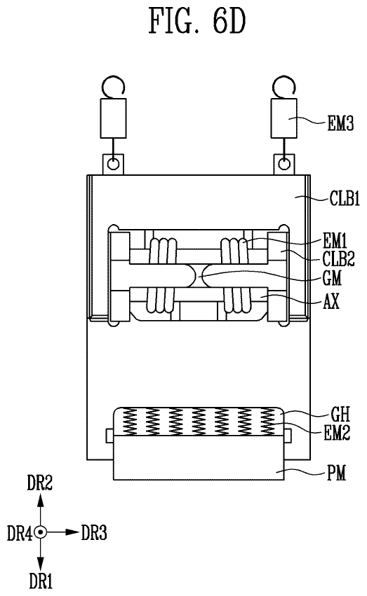

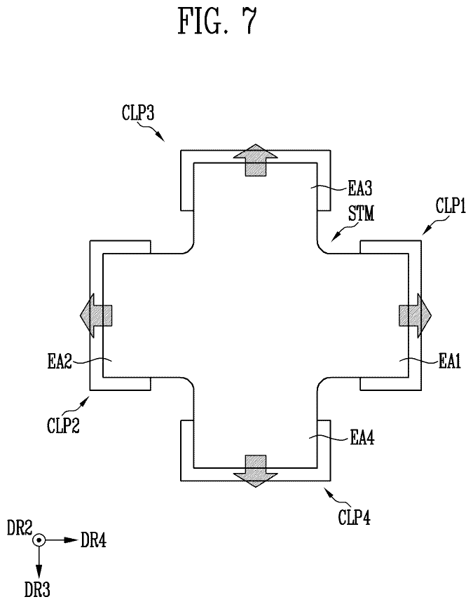

FIG. 4 is a conceptual view illustrating an embodiment of an apparatus for manufacturing a display device. FIG. 5A is a plan view illustrating an embodiment of a stamp member of the apparatus shown in FIG. 4. FIG. 5B is a plan view illustrating an embodiment of the stamp member shown in FIG. 5A. FIG. 6A is a plan view illustrating an embodiment of a clamping unit of the apparatus shown in FIG. 4. FIG. 6B is a side view of a first clamper shown in FIG. 6A. FIG. 6C is a rear view of the first clamper shown in FIG. 6A. FIG. 6D is a front view of the first clamper shown in FIG. 6A. FIG. 7 is a conceptual view schematically illustrating a state in which the clamping unit of the apparatus shown in FIG. 4 extends the stamp member.

Referring to FIG. 4, an embodiment of the apparatus 100 may include a stamp member STM, a stamp head unit SHP, a clamping unit CLP, a pressurizing unit PP, and a stage SG.

Referring to FIGS. 5A and 5B together, the stamp member STM may include an adsorption area AA and first to fourth edge areas EA1 to EA4 surrounding the adsorption area AA in different directions.

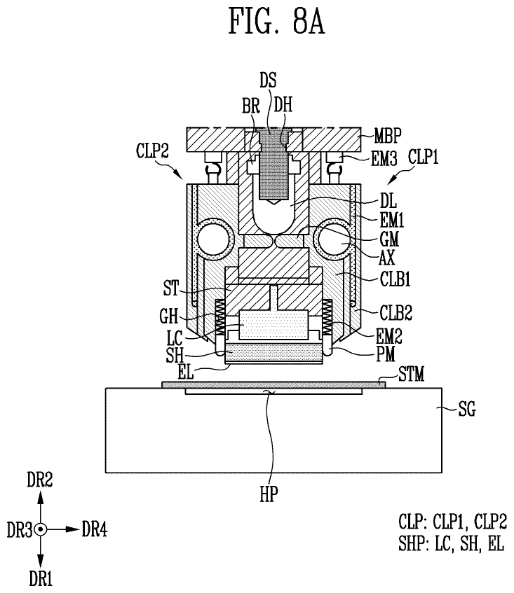

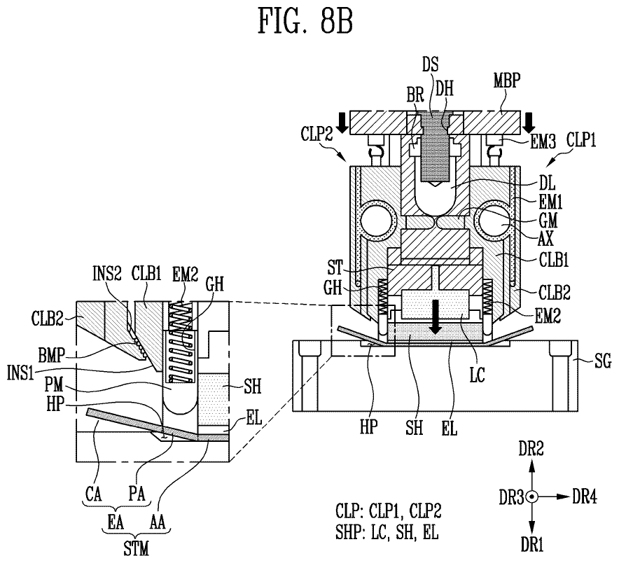

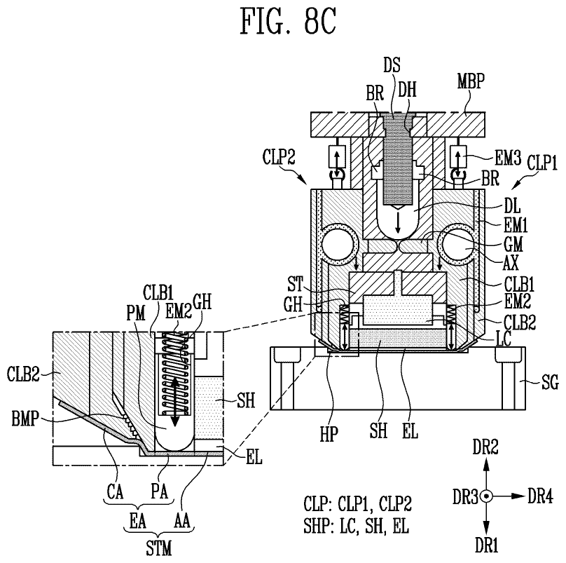

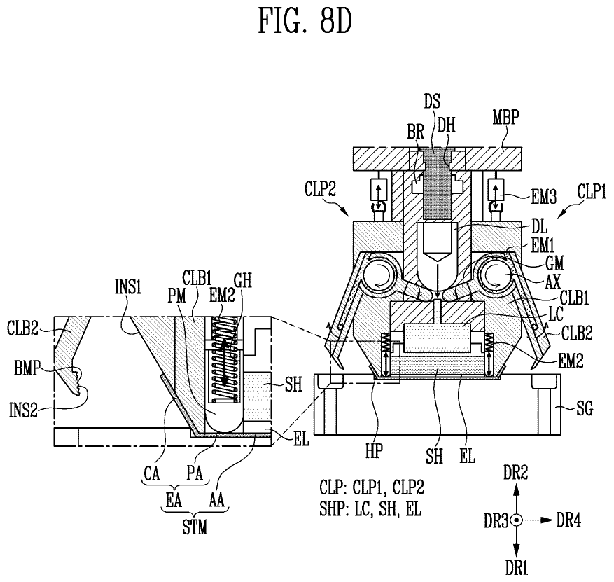

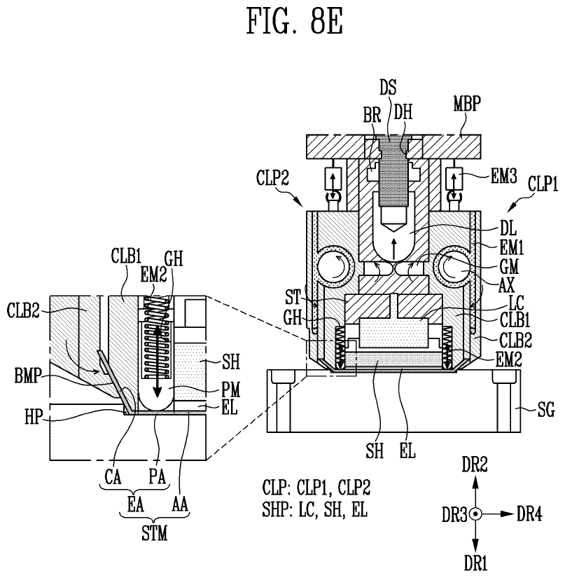

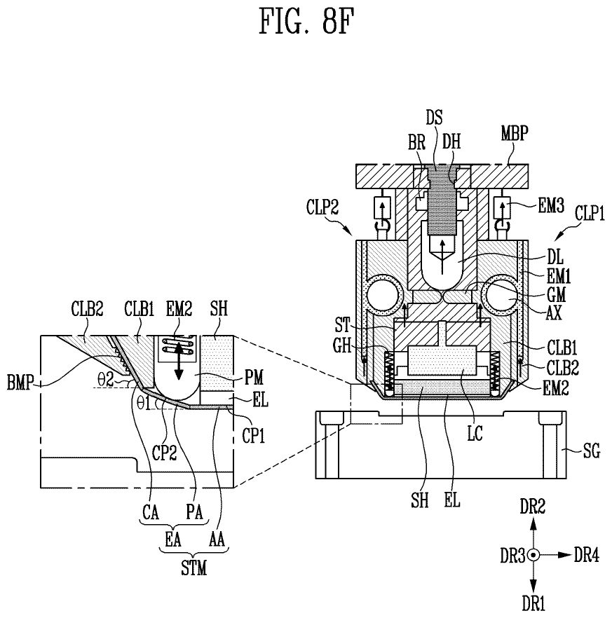

The stamp member STM may be used to transfer the light emitting elements LE described with reference to FIG. 3 onto the pixel circuit layer PCL of the display device 10 from an intermediary member such as a donor substrate or a carrier substrate. An embodiment of a method of transferring the light emitting elements LE onto the pixel circuit layer PCL, using the stamp member, as described above will be described in detail later with reference to FIGS. 8A to 8F, 9A to 9C, and 10A to 10F.

Referring to FIG. 5A, the adsorption area AA of the stamp member STM may correspond to an area adsorbed onto the stamp head unit SHP which will be described later.

In an embodiment, as shown in FIG. 5A, each of the first to fourth edge areas EA1 to EA4 of the stamp member STM may include a first non-adsorption area NA1 relatively adjacent to the adsorption area AA and a second non-adsorption area NA2 relatively more distant from the adsorption area AA than the first non-adsorption area NA1. A width of the first non-adsorption area NA1 may gradually decrease along a direction distant (or a direction being away) from the adsorption area AA. In addition, a width W2 of the second non-adsorption area NA2 may be constant along a direction distant from the adsorption area AA. The width W2 of the second non-adsorption area NA2 may be smaller than a width (a maximum width) W1 of the adsorption area AA.

In embodiments, the width of the first non-adsorption area NA1 in an area adjacent to the adsorption area AA (the maximum width) may be equal to the width W1 of the adsorption area AA, and a width of the first non-adsorption area NA1 in an area adjacent to the second non-adsorption area NA2 (a minimum width) may be equal to the width W2 of the second non-adsorption area NA2. In an embodiment, for example, the width of the first non-adsorption area NA1 may non-linearly decrease from the width W1 of the adsorption area AA to the width W2 of the second non-adsorption area NA2. Through this structure, when a boundary line of the adsorption area AA and the first to fourth edge areas EA1 to EA4 is folded, stress concentrating on both opposing end portions of the boundary line can be reduced.

Referring to FIG. 5B, in another embodiment, a width of each of first to fourth edge areas EA1′ to EA4′ of a stamp member STM′ may gradually decrease along a direction distant from the adsorption area AA. In an embodiment, for example, the width of each of the first to fourth edge areas EA1′ to EA4′ may gradually decrease from the width W1 of the adsorption area AA and then have the width of W2 at an end portion of each of the first to fourth edge areas EA1′ to EA4′. In such an embodiment, the first to fourth edge areas EA1′ to EA4′ may have a shape corresponding to the first non-adsorption area NA1 except the second non-adsorption area NA2 shown in FIG. 5A. Through this structure, when a boundary line of the adsorption area AA and the first to fourth edge areas EA1′ to EA4′ is folded, stress concentrating on both opposing end portions of the boundary line can be reduced.

Referring back to FIG. 4, the stamp head unit SHP may be disposed at a lower portion of the main body unit MBP, to adsorb the adsorption area (AA shown in FIGS. 5A and 5B) of the stamp member STM.

The stamp head unit SHP may include a stamp head SH, a load cell LC, and an elastic body EL.

In embodiments, the stamp head SH may adsorb the adsorption area AA of the stamp member STM, using various methods, such as an electrostatic chuck, an adhesive chuck, a vacuum chuck, and a porous vacuum chuck, thereby fixing or moving a position of the stamp member STM.

The load cell LC may be disposed at an upper side of the stamp head SH to measure a pressure applied to the stamp head SH. In an embodiment, for example, when the stamp head SH is adhered closely to a base surface of the stage SG in a state in which the stamp head SH adsorbs the stamp member STM, the load cell LC may monitor a pressure applied to the stamp member STM. The load cell LC may transfer information on the pressure applied to the stamp member STM to a controller (not shown), and the controller may transmit a signal for driving the main body unit MBP or a driving rod DL to maintain a range in which the stamp member STM is not pressurized more than necessary so as to prevent deformation or damage of the stamp member STM.

The elastic member EL is a component which provides a surface on which the stamp head unit SHP is in contact with the stamp member STM, and rubber such as polyurethane (PU) may be used as the elastic member EL. However, embodiments are not limited thereto. In another embodiment, for example, the elastic body EL may absorb an impact applied to the stamp member STP when the stamp head unit SHP adsorbs the stamp member STM, and be provided with a material having high resilience.

The main body unit MBP is a kind of frame which provides a space in which other components of the apparatus 100 are mechanically installed, and may be configured to be movable along a first direction DR1 facing the stamp member STM and a second direction DR2 as the opposite direction of the first direction DR1.

For convenience of illustration and description, although not shown in the drawings, the apparatus 100 may further include a body driving unit (not shown) which provides a predetermined driving force to the main body unit MBP such that the main body unit MBP can vertically move along the first direction DR1 and the second direction DR2.

The clamping unit CLP is a component which clamps and extends the stamp member STM, and may be installed to be movable along a first direction DR1 and a second direction DR2 in the main body unit MBP. In embodiments, the clamping unit CLP may be configured to allow the main body unit MBP to slide in the first direction DR1 and the second direction DR2 along an extended surface. The clamping unit CLP will be described in detail below with reference to FIGS. 6A to 6D.

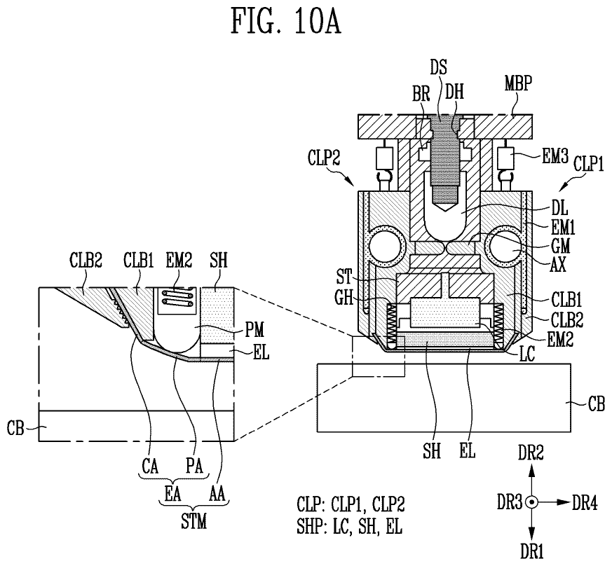

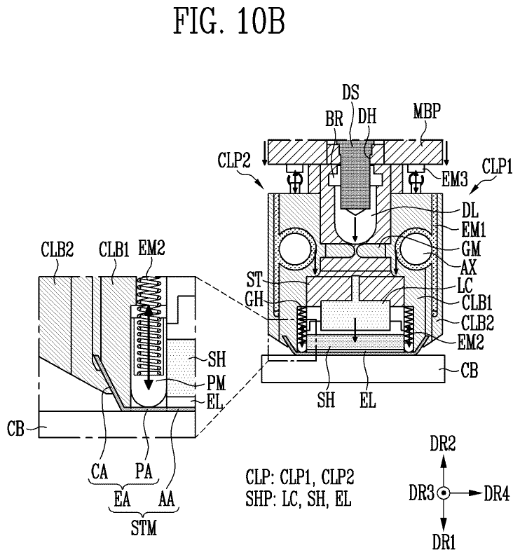

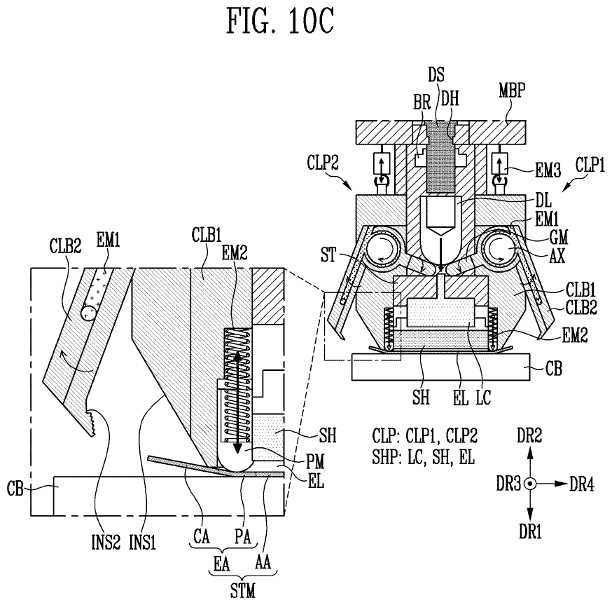

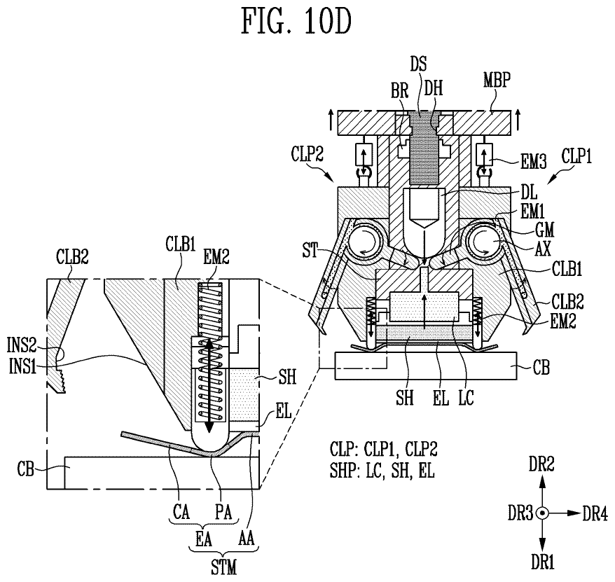

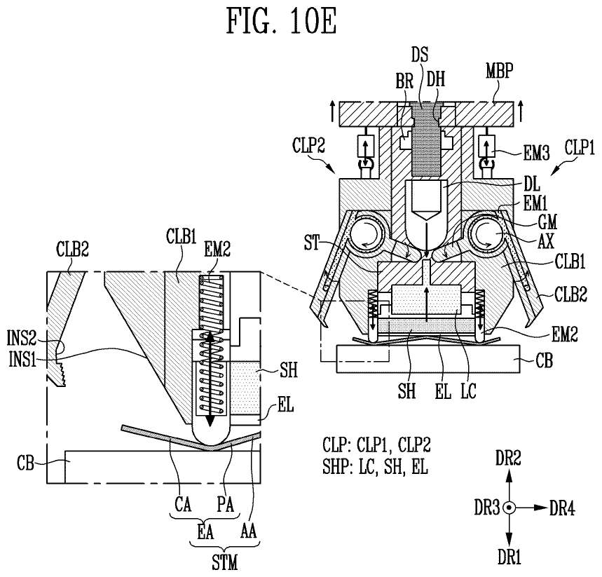

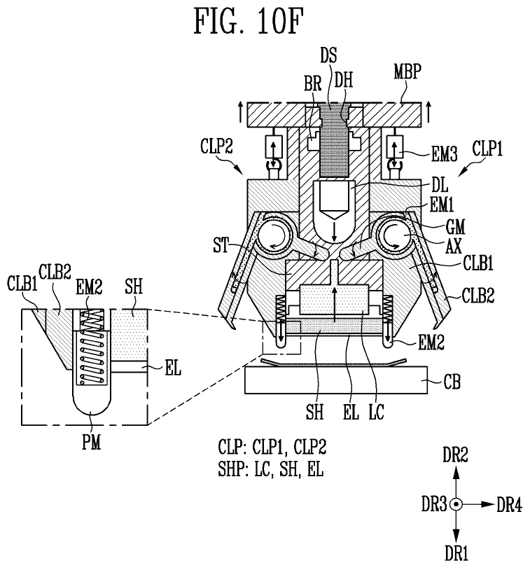

The pressurizing unit PP is a component which transfers a force pressurizing the clamping unit CLP in the first direction to the clamping unit CLP, and may be installed to be movable along the first direction DR1 and the second direction DR2 in the main body unit MBP. The pressurizing unit PP may be configured to operate in one of a first mode in which the clamping unit CLP is not pressurized and a second mode in which the clamping unit CLP is pressurized. The apparatus 100 may be driven to clamp and extend the stamp member STM according to the operation mode of the pressurizing unit PP. This will be described in detail later with reference to FIGS. 8A to 8F and 10A to 10F.

The pressurizing unit PP may include a driving bracket DB, a driving chamber DC, a driving shaft DS, and the driving rod DL.

The driving bracket DB may be installed at an upper side of the main body unit MBP as a body of the pressurizing unit PP, and provide a space in which other components of the pressurizing unit PP can be installed.

The driving chamber DC is an empty space provided inside the driving bracket DB, and may provide a space in which the driving shaft DS which will be described later moves along the first direction DR1 and the second direction DR2.

The driving shaft DS is a component which transfers a force in the first direction DR1 to the driving rod DL, and may extend to the inside of the main body unit MBP along the first direction DR1 from the inside of the driving chamber DC. In other words, an upper portion of the driving shaft DS may be installed inside the driving chamber DC, and a lower portion of the driving shaft DS may extend to an inner space of the main body unit MBP while penetrating a driving hole DH formed in the main body unit MBP.

The main body unit MBP may include a bearing BR which limits movement in a third direction DR3 and a fourth direction DR4, which intersect the first direction DR1 and the second direction DR2, such that the driving shaft DS moves along only the first direction DR1 and the second direction DR2. Through this structure, the upper portion of the driving shaft DS may slide in the first direction DR1 and the second direction DR2 along an inner surface of the driving chamber DC, and accordingly, the lower portion of the driving shaft DS may also move in the first direction DR1 and the second direction DR2 in the inner space of the main body unit MBP.

The driving rod DL may be installed at a lower portion of the driving shaft DS. When the driving shaft DS descends, the driving rod DL may transfer a force in the first direction DR1 to the clamping unit CLP while being in contact with the clamping unit CLP.

Hereinafter, the clamping unit CLP will be described in detail with reference to FIGS. 6A to 6D and 7 together.

First, referring to FIGS. 6A and 7 together, the clamping unit CLP may include first to fourth clampers CLP1 to CLP4.

On a plane formed by the third direction DR3 and the fourth direction DR4, the first to fourth clampers CLP1 to CLP4 may be respectively disposed at a right side, a left side, an upper side, and a lower side with respect to a position (see a dotted line circle shown in FIG. 6A) at which the driving rod DL pressurizes the clamping unit CLP.

As shown in FIG. 7, the first to fourth clampers CLP1 to CLP4 may clamp and extend the first to fourth edge areas EA1 to EA4 of the stamp member STM, respectively. In an embodiment, for example, on a plane defined by the third direction DR3 and the fourth direction DR4, the first clamper CLP1 may clamp the first edge area EA1 of the stamp member STM, and extend the first edge area EA1 to the right side with respect to the adsorption area AA. In such an embodiment, the second clamper CLP2 may clamp the second edge area EA2 of the stamp member STM, and extend the second edge area EA2 to the right side with respect to the adsorption area AA. In addition, the third clamper CLP3 may clamp the third edge area EA3 of the stamp member STM, and extend the third edge area EA3 to the upper side with respect to the adsorption area AA. In such an embodiment, the fourth clamper CLP4 may clamp the fourth edge area EA4 of the stamp member STM, and extend the fourth edge area EA4 to the lower side with respect to the adsorption area AA.

In such an embodiment, the clamping unit CLP can extend the stamp member STM in four different directions, and thus wrinkles can be effectively prevented from being formed as the stamp member STM is not sufficiently planarized in a process of transferring the light emitting element LE onto the pixel circuit layer PCL. When the process of transferring the light emitting element LE is performed in a state in which wrinkles are formed in the stamp member STM, an area, in which the stamp member STM and the pixel circuit layer PCL are not in contact with each other, may be generated. Therefore, the light emitting element LE may not be effectively transferred onto a partial area of the pixel circuit layer PCL, and hence a defect of the display device 10 may occur. In the apparatus 100 in accordance with embodiments of the disclosure, the clamping unit, which extends the stamp member STM in four different directions as described above, is provided, such that the transfer reliability of the light emitting element LE can be improved, thereby reducing a risk that the light emitting element LE will not be transferred. In such embodiments, the yield of the display device 10 can be increased.

Referring back to FIG. 4, each of the first to fourth clampers CLP1 to CLP4 may include a first clamping body CLB1, a rotating shaft AX, a second clamping body CLB2, and a first elastic member EM1.

The first to fourth clampers CLP1 to CLP4 are different from one another in that the first to fourth clampers CLP1 to CLP4 clamp different edge areas of the stamp member STM, but substantially the same as each other in that the first to fourth clampers CLP1 to CLP4 all perform a same function of clamping the stamp member STM. Therefore, for convenience of description, the first clamper CLP1 will be mainly described below with reference to FIGS. 6A to 6D, and any repetitive detailed descriptions of the second to fourth clampers CLP2 to CLP4 will be omitted.

Referring to FIGS. 4 and 6A to 6D together, the first clamping body CLB1 is a component which provides a space in which other components of the first clamper CLP1 are installed, and may be installed to be slidable along the first direction DR1 and the second direction DR2 in the main body unit MBP.

The rotating shaft AX may be installed to be rotatable with respect to the third direction DR3 intersecting the first direction DR1 in the first clamping body CLB1.

The second clamping body CLB2 may be installed at the rotating axis AX to rotatably move with respect to the rotating shaft AX between a clamping posture P1 at which the stamp member STM is clamped and an open posture P2 at which the stamp member STM is not clamped. Referring to FIG. 6B, the second clamping body CLB2 is rotatable with respect to the rotating shaft AX, and may be positioned in one of the clamping posture P1 and the open posture P2.

In an embodiment, the second clamping body CLB2 may include a guide member GM extending in a radius direction of the rotating shaft AX. The guide member GM may receive a force with which the driving rod DL pressurizes in the first direction DR1 to move the entire clamping unit CLP in the first direction DR1 or rotate the second clamping body CLB2 with respect to the rotating shaft AX.

Referring to FIG. 6A, with respect to any one of the first to fourth clampers CLP1 to CLP4, the guide member GM may have a shape with a width linearly decreasing along a direction facing another of the first to fourth clampers CLP1 to CLP4, which faces the one clamper in the third direction DR3 or the fourth direction DR4. In an embodiment, for example, a guide member of the first clamper CLP1 may have a shape with a width linearly decreasing along a direction (i.e., the opposite direction of the fourth direction DR4) facing the second clamper CL2 facing the first clamper CL1 in the fourth direction DR4. In other words, the guide member GM may have a trapezoidal shape in which a width of one end portion pressurized by the driving rod DL is smaller than a width of the first clamping body CLB1, but embodiments are not limited thereto. In another embodiment, for example, although not shown in the drawing, the one end portion of the guide member GM, which is pressurized by the driving rod DL, may have a sharp triangular shape.

In an embodiment, like the above-described guide member GM of the first clamper CL1, guide members GM of the second to fourth clampers CLP2 to CLP4 may also have a trapezoidal or triangular shape with a width gradually decreasing along a direction distant from the first clamping body CLB1. In such an embodiment, the guide members GM of the first to fourth clampers CLP1 to CLP4 may substantially simultaneously receive a force with which the driving rod DL applies in the first direction DR1, and therefore, the postures of the first to fourth clampers CLP1 to CLP4 may be simultaneously changed from the clamping posture P1 to the open posture P2 or from the open posture P2 to the clamping posture P1.

The main body unit MBP may include a stopper ST which limits movement of the clamping unit CLP in the first direction DR1 when the pressurizing unit PP is in the second mode. That is, when the driving rod LD pressurizes the guide member GM in the first direction DR1, the clamping unit CLP may linearly move in the first direction DR1 until before the first clamping body CLB1 is in contact with the stopper ST of the main body unit MBP. At the moment when the first clamping body CLB1 is in contact with the stopper ST, the first clamping body CLB1 cannot slide any more along the first direction DR1 in which the main body unit MBP extends. Accordingly, the force with which the driving rod DL pressurizes the guide member GM in the first direction DR1 may be changed to a force with which the second clamping body CLB2 is rotated with respect to the rotating axis AX. An interaction between the driving rod DL and the guide member GM will be described in detail later with reference to FIGS. 8A to 8F and 10A to 10F.

In an embodiment, as shown in FIG. 6C, the first elastic member EM1 may be installed between the rotating shaft AX and the second clamping body CLB2, to apply, to the second clamping body CLB2, a force with which the second clamping body CLB2 is adhered closely to the first clamping body CLB1. In embodiments, the first elastic member EM1 may be configured as a torsional spring, but the disclosure is not necessarily limited thereto. In an embodiment, for example, the first elastic member EM may include or be configured as any material having an elastic force, which is installed at the rotating shaft AX, such as the torsional spring, to apply, to the second clamping body CLB2, a compressive force with which the second clamping body CLB2 is adhered closely to a side of the first clamping body CLB1.

When any force is not applied to the first elastic member EM1, the first elastic member EM1 may apply a predetermined force to the second clamping body CLB2 in a direction in which the second clamping body CLB2 is adhered closely to the first clamping body CLB1, i.e., clockwise with respect to the rotating shaft AX in FIGS. 4 and 6B. In this state, when the force which the driving rod DL applies to the guide member GM is changed to a force with which the second clamping body CLB2 is rotated counterclockwise, the first elastic member EM1 may apply, to the second clamping body CLB2, a restoring force in a direction which the second clamping body CLB2 be returned to an original position at which the second clamping body CLB2 is again adhered closely to the first clamping body CLB1, i.e., clockwise.

Further referring to FIG. 6B, the first clamping body CLB1 may include a first inclined surface INS1 on which one surface of the first edge area EA1 of the stamp member STM is settled. In addition, the second clamping body CLB2 may include a second inclined surface INS2 on which an opposite surface of the first edge area EA1 of the stamp member STM is settled. In addition, a plurality of bumps BMP which fix the opposite surface of the first edge area EA1 of the stamp member STM may be defined or formed on the second inclined surface INS2 of the second clamping body CLB2.

The above-described clamping posture P1 of the second clamping body CLB2 may mean a posture at which the first inclined surface INS1 and the second inclined surface INS2 are relatively adjacent to each other as the guide member GM linearly moves. In other words, the clamping posture P1 of the second clamping body CLB2 may mean a state before the force which the driving rod DL applied to the guide member GM is yet changed to the force with which the second clamping body CLB2 is rotated. The second clamping body CLB2 may maintain a state in which the second clamping body CLB2 is adhered closely to the first clamping body CLB1 by a force which the first elastic member EML applies to the second clamping body CLB2.

In addition, the above-described open posture P2 of the second clamping body CLB2 may mean a posture at which the first inclined surface INS1 and the second inclined surface INS2 are relatively spaced apart from each other as the guide member GM rotatably moves. In other words, the open posture P2 of the second clamping body CLB2 may mean a state after the force which the driving rod DL applied to the guide member GM is yet changed to the force with which the second clamping body CLB2 is rotated. The second clamping body CLB2 may maintain a state in which the second clamping body CLB2 is spaced apart from the first clamping body CLB1 by the force which the driving rod DL applies to the guide member GM.

Referring back to FIG. 4, the stage SG may be disposed while being spaced apart from the stamp head unit SHP in the first direction DR1, to support at least a portion of the first to fourth edge areas EA1 to EA4 of the stamp member STM. The stage SG may include a groove portion HP recessed from an upper surface thereof in the first direction DR1. The groove portion HP may accommodate the adsorption area AA of the stamp member STM when the pressurizing unit PP is in the second mode.

Referring to FIGS. 6B and 6D together, the clamping unit CLP may further include a pressing member PM, a guide groove GH, and a second elastic member EM2.

The pressing member PM may be accommodated in the guide groove GH as an empty space formed at a lower end of the first clamping body CLB1, to slide in the first direction DR1 and the second direction DR2 along the guide groove GH. The pressing member PM may pressurize a pressing area PA of the stamp member STM.

The guide groove GH is an empty space formed at a lower end of the first clamping body CLB1, and may accommodate the pressing member PM such that the pressing member PM is slidable along the first direction DR1 and the second direction DR2.

The second elastic body EM2 may be installed in the guide groove GH, to apply a restoring force in the first direction DR1 to the pressing member PM when the pressing member PM is compressed in the second direction DR2. In other words, one end of the second elastic member EM2 may be fixed to the guide groove GH and the other end of the second elastic member EM2 is connected to the pressing member PM, to provide a predetermined elastic force to the pressing member PM. In embodiments, the second elastic member EM2 may be configured as a compression spring, but the disclosure is not limited thereto. In another embodiment, for example, the second elastic member EM2 may include or be configured as any material having an elastic force, which is installed in the guide groove GH, such as the torsional spring, to apply the restoring force in the first direction DR1 to the pressing member PM when the pressing member PM is compressed in the second direction DR2.

Referring to FIGS. 4 and 6B to 6D together, the apparatus 100 in accordance with the embodiments of the disclosure may further include a third elastic member EM3.

The third elastic member EM3 may connect between the main body unit MBP and the clamping unit CLP. The third elastic member EM3 may be elongated when the pressurizing unit PP operates in the second mode, i.e., when the driving rod DL pressurizes the guide member GM in the first direction DR1, to apply a restoring force in the second direction DR2 to the clamping unit CLP. Accordingly, when the driving rod DL releases the force applied to the guide member GM (i.e., when the mode of the pressurizing unit PP is changed from the second mode to the first mode), the clamping unit CLP may be moved in the second direction DR2 by the restoring force of the third elastic member EM3 even when any separate driving force is not provided to the clamping unit CLP. In embodiments, the third elastic member EM3 may be configured as an extension spring, but the disclosure is not necessarily limited thereto. In another embodiment, for example, the third elastic member EM3 may include or be configured as any material having an elastic force, which connects between the main body unit BMP and the clamping unit CLP, such as the extension spring, to extend when the clamping unit CLP moves in the first direction DR1 and apply, to the clamping unit CLP, a restoring force with which the clamping unit CLP is pulled in the second direction DR2.

Although will be described later, a force with which the clamping unit CLP can clamp the first to fourth edge areas EA1 to EA4 of the stamp member EA1 to EM4 and then extend the stamp member STM in four different directions is related to the restoring force of the third elastic member EM3. This will be described in more detail below.

Hereinafter, stages in which the apparatus 100 in accordance with the embodiments of the disclosure clamps and extends the stamp member STM will be described in detail with reference to FIGS. 8A to 8F.

FIGS. 8A to 8F are conceptual views schematically illustrating operation stages in which the apparatus clamps and extends the stamp member in accordance with an embodiment of the disclosure.

In FIGS. 8A to 8F, the same or like elements as those shown in FIGS. 4, 5A, 5B, 6A to 6D, and 7 are labeled with the same reference characters as used above to describe the embodiment of the apparatus for manufacturing the display device above, and any repetitive detailed description thereof will hereinafter be omitted or simplified. In addition, in FIGS. 8A to 8F, some components of the pressurizing unit PP, i.e., the driving bracket DB, the driving chamber DC, and a portion of an upper end of the driving shaft DS will be omitted for convenience of illustration. Particularly, for convenience of description, in FIGS. 8B to 8F, the second clamper CLP2 among the first to fourth clampers CLP1 to CLP4 and the second edge area EA2 of the stamp member STM, which is clamped and extended by the second clamper CLP2, will be enlarged and described in detail. That is, descriptions of the first clamper CLP1, and the third clamper CLP3, and the fourth clamper CLP4, the first edge area EA1, the third edge area EA3, and the fourth edge area EA4 of the stamp member STM may be substantially the same as descriptions of the second clamper CLP2 and the second edge area EA2 of the stamp member STM, and any repetitive detailed descriptions thereof will be omitted.

FIG. 8A illustrates a state in which the pressurizing unit PP operates in the first mode. That is, the pressurizing unit PP does not pressurize the clamping unit CLP, and the driving rod DL may maintain a state in which the driving rod DL is in contact with the guide member GM of the clamping unit CLP.

FIG. 8B illustrates a state in which the mode of the pressurizing unit PP is changed from the first mode to the second mode. When the mode of the pressurizing unit PP is changed from the first mode to the second mode, the driving shaft DS may apply a force to the driving rod DL in the first direction DR1. Accordingly, the driving rod DL may pressurize the guide member GM in the first direction DR1. The force in the first direction DR1, which is applied to the guide member GM as described above, may be smaller than a compressive force with which the first elastic member EM1 allows the first clamping body CLB1 and the second clamping body CLB2 to be adhered closely to each other. In other words, at an initial stage in which the pressurizing unit PP enters into the second mode, the force which the driving rod DL applies to the guide member GM may not be greater than the compressive force of the first elastic member EM1 to a degree to which the guide member GM is rotated counterclockwise as the force exceeds the compressive force of the first elastic member EM1.

Accordingly, the force which the driving rod DL applies to the guide member GM may be entirely used as a driving force with which the main body unit MBP can move in the first direction DR1. In other words, just after the mode of the pressurizing unit PP is changed to the second mode, i.e., until before the clamping unit CLP is in contact with the stopper ST, the clamping unit CLP may be linearly moved in the first direction DR1 by the force which the driving rod DL applies to the guide member GM. As such, when the mode of the pressurizing unit PP is changed from the first mode to the second mode, the stamp head unit SHP may move in the first direction DR1 as the main body unit MBP moves in the first direction DR1.

In an embodiment, each of the first to fourth edge areas EA1 to EA4 of the stamp member STM may include a pressing area PA adjacent to the adsorption area AA and a clamping area CA except the pressing area PA. The first to fourth edge areas EA1 to EA4 have same material properties and same features except for directions in which the first to fourth edge areas EA1 to EA4 extend from the adsorption area AA of the stamp member STM. Therefore, hereinafter, for convenience of description, a pressing area PA and a clamping area CA of the second edge area EA2 will be mainly described as described above.

When the mode of the pressing unit PP is changed from the first mode to the second mode, the stamp head unit SHP may allow the stamp member STM to enter into the groove portion HP of the stage SG in a state in which the adsorption area AA of the stamp member STM is adsorbed by a force with which the main body unit MBP moves in the first direction DR1. Accordingly, a boundary surface between the adsorption area AA of the stamp member AA and the pressing area PA may be bent. The adsorption area AA of the stamp member STM may be adhered closely to a bottom surface of the groove portion HP of the stage SG by pressurization of the stamp head unit SHP, and the pressing area CA and the clamping area CA may be bent at a predetermined angle in a direction facing the second direction DR2 with respect to the adsorption area AA.

FIG. 8C illustrates a moment when the clamping unit CLP is in contact with the stopper ST of the main body unit MBP when the pressurizing unit PP operates in the second mode.

Referring to FIG. 8C, as the state in which the pressurizing unit PP is in the second mode after the mode of the pressurizing unit PP is changed from the first mode to the second mode is continued as described with reference to FIG. 8B, the clamping unit CLP may be moved together with the main body unit MBP in the first direction DR1 by a force with which the driving rod DL pressurizes the guide member GM. As a result, the clamping unit CLP may be in contact with the stopper ST.

As such, when the second clamper CLP2 is moved in the first direction DR1 by the force with which the driving rod DL pressurizes the guide member GM in the first direction DR1, the pressing member PM of the second clamper CLP2 may also be moved in the first direction DR1, thereby pressurizing the pressing area PA of the stamp member STM. In other words, after the stamp member STM is in contact with the bottom surface of the groove portion HP of the stage SG, the pressing member PM may be moved at a predetermined distance in the first direction DR1 by a force with which the second clamper CLP2 pressurizes the guide member GM, thereby pressurizing the pressing area PA. Accordingly, like the adsorption area AA, the pressing area PA of the stamp member STM may be adhered closely to the bottom surface of the groove portion HP of the stage SG. In addition, the clamping area CA of the stamp member STM may receive a repulsive force in the second direction while being in contact with a corner of the groove portion HP, to be bent at a predetermined angle in a direction facing the second direction DR2.

The force with which the pressing member PM pressurizes the pressing area PA may be a restoring force of the second elastic member EM2 in the first direction DR1. In other words, the pressing member PM may be compressed in the second direction DR2 by the force with which the pressing area PA is pressurized, and pressurize the pressing area PA in the first direction DR1 with a restoring force with respect to the compression in the second direction DR2.

FIG. 8D illustrates a state after the clamping unit CLP is in contact with the stopper ST of the main body unit MBP when the pressurizing unit PP operates in the second mode.

Referring to FIG. 8D, after the clamping unit CLP is in contact with the stopper ST, the stopper ST may limit movement of the clamping unit CLP in the first direction DR1. That is, the force with which the driving rod DL pressurizes the guide member GM no longer acts as a driving force with which the clamping unit CLP is moved in the first direction DR1. Instead, the force with which the driving rod DL pressurizes the guide member GM may be changed to a force with which the second clamping body CLB2 is rotated with respect to the rotating shaft AX.

FIG. 8D illustrates a state in which the second clamping body CLB2 is rotated with respect to the rotating shaft AX by the force with which the driving rod DL pressurizes the guide member GM in the first direction DR1. In an embodiment, for example, the second clamping body CLB2 may be rotated clockwise with respect to the rotating shaft AX. Accordingly, the second clamping body CLB2 may be positioned in the open posture. That is, the second clamping body CLB2 may move in a direction in which the second inclined surface INS2 of the second clamping body CLB2 becomes distant from the first inclined surface INS1 of the first clamping body CLB1. When the second clamper CLP2 is positioned in the open posture as described above, the clamping area CA of the stamp member STM may be adhered closely to the first inclined surface INS1 of the first clamping body CLB1.

FIG. 8E illustrates a state just after the mode of the pressurizing unit PP is changed from the second mode to the first mode.

Referring to FIG. 8E, as the mode of the pressurizing unit PP is changed from the second mode to the first mode, the driving rod DL may move in the second direction DR2, thereby no longer applying the force in the first direction DR1 to the guide member GM. Accordingly, the second clamping body CLB2 may be rotated with respect to the rotating shaft AX by a restoring force of the first elastic member EM1. In an embodiment, for example, the second clamping body CLB2 of the second clamper CLP2 may be rotated counterclockwise with respect to the rotating shaft AX by the restoring force of the first elastic member EM1 as the force with which the driving rod DL has pressurized the guide member GM disappears. Accordingly, the posture of the second clamping body CLB2 may be changed from the open posture to the clamping posture. In other words, the second clamping body CLB2 may be rotated in a direction in which the second inclined surface INS2 of the second clamping body CLB2 approaches the first inclined surface INS1 of the first clamping body CLB1. According to this driving, the first to fourth clampers CLP1 to CLP4 may respectively clamp the first to fourth edge areas EA1 to EA4 of the stamp member STM when the mode of the pressurizing unit PP is changed from the second mode to the first mode.

FIG. 8E illustrates a state just after the mode of the pressurizing unit PP is changed from the second mode to the first mode, and this may mean that the clamping unit CLP still maintains the state in which the clamping unit CLP is in contact with the stopper ST. In an embodiment, just after the mode of the pressurizing unit PP is changed from the second mode to the first mode, the first clamping body CLB1 does not start being slid in the second direction DR2 by a restoring force of the third elastic member EM3 even when the force with which the driving rod DL has applied to the guide member GM is released. Instead, the posture of the second clamping body CLB2 may be returned to the clamping posture by the restoring force of the first elastic member EM1 just after the force with which the driving rod DL has applied to the guide member GM is released.

In an embodiment, when the mode of the pressurizing unit PP is changed from the second mode to the first mode, the adsorption area AA of the stamp member STM may be in contact with the stamp head unit SHP. In addition, the pressing area PA of the stamp member STM may be in contact with the pressing member PM. In addition, the clamping area CA of the stamp member STM may be clamped by the second clamper CLP2. For convenience of description, the second clamper CLP2 is mainly described with reference to FIG. 8E. However, descriptions of the first clamper CLP1, the third clamper CLP3, and the fourth clamper CLP4 may also be the same as that described with reference to the second clamper CLP2. In other words, the pressing member PA of the stamp member STM may be in contact with the pressing member PM. In addition, the clamping area CA of the stamping member STM may be in contact with the clamping unit CLP.

FIG. 8F illustrates a state in which the driving rod DL continuously moves in the second direction DR2 after the posture of the clamping unit CLP is changed to the clamping posture when the pressurizing unit PP is in the first mode.

Referring to FIG. 8F, the driving rod DL may continuously move in the second direction DR2 even after the posture of the clamping unit CLP is changed from the open posture to the clamping posture. Accordingly, the clamping unit CLP may be moved in the second direction DR2 by the restoring force of the third elastic member EM3 in the second direction DR2. As a result, the clamping unit CLP may be separated from the stopper ST. Since the clamping unit CLP is in a state in which the clamping unit CLP clamps the clamping area CA of the stamp member STM as described in FIG. 8E, tensile forces in different directions may be applied to the adsorption area AA of the stamp member STM when the clamping unit CLP moves in the second direction DR2 in a state in which the main body unit MBP is fixed. As such, the first to fourth clampers CLP1 to CLP4 extends the stamp member STM in four different directions, so that the adsorption area AA of the stamp member STM can be flattened.

In an embodiment, when the clamping unit CLP moves in the second direction DR2 after the mode of the pressurizing unit PP is changed from the second mode to the first mode, i.e., in a state in which the posture of the clamping unit CLP is changed from the open posture to the clamping posture, a degree to which one of the clamping areas CA is bent with respect to the adsorption area AA may be greater than a degree to which a corresponding one of the pressing areas CA is bent with respect to the adsorption area AA. In an embodiment, for example, an angle θ2 formed by the adsorption area AA and the clamping area CA may be greater than an angle θ1 formed by the adsorption area AA and the pressing area PA. In other words, a position CP1 at which the adsorption area AA and the stamp head unit SHP are in contact with each other may be closer to the stage SG than a position CP2 at which any one of the pressing areas PA is in contact with the pressing member PM. The pressing member PM may move at a predetermined distance in the second direction DR2, and accordingly, the second elastic member EM2 may be compressed in the second direction to apply the restoring force in the first direction DR1 to the pressing area PA, such that the tensile force applied to the adsorption area AA can be reinforced.

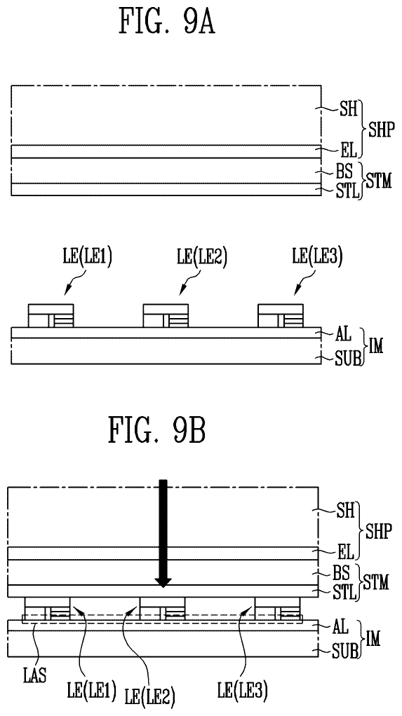

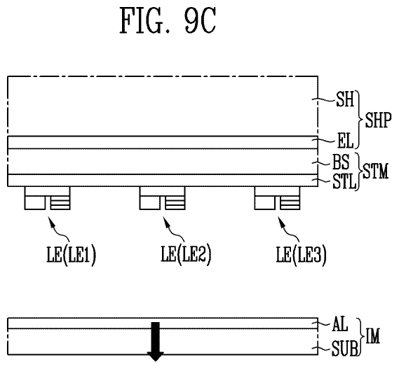

FIGS. 9A to 9C are conceptual views schematically illustrating a process of transferring light emitting elements disposed on an intermediary member onto a stamp member.

First, referring to FIG. 9A, an intermediary member IM is a component temporarily used in a process in which light emitting elements LE are transferred onto a stamp member STM from a growth substrate (not shown). In an embodiment, for example, the intermediary member IM may be a carrier wafer, a donor plate, or a receiver substrate.

The intermediary member IM may include a substrate SUB and an adhesive layer AL.

The substrate SUB may include a relatively rigid material, and provide or define a base on which the adhesive layer AL is disposed.

The adhesive layer AL may be a layer including polymer. In an embodiment, for example, the adhesive layer AL may include at least one selected from epoxy resin, phenolic resin, polyimide resin, polyurethane resin, melamine resin, and urea resin. However, embodiments are not limited thereto.

The adhesive layer AL may be a layer in contact with the light emitting elements LE. In an embodiment, for example, since the adhesive layer AL may include polymer, the adhesive layer AL may have adhesive properties with respect to the light emitting elements LE.

The stamp member STM may include a stamp base BS and a stamp layer STL.

The stamp base BS may provide or define a base on which the stamp layer STL is disposed. In embodiments, the stamp base BS may include various rigid or flexible materials. In an embodiment, for example, the stamp base BS may include polyethylene terephthalate (PET) or polycarboxylate ether (PCE). Alternatively, the stamp base BS may include ultra thin glass (UTG). However, embodiments are not limited thereto.

The stamp layer STL may be disposed on the stamp base BS. The stamp layer STL may provide an area in which the light emitting elements LE can be attached.

Referring to FIG. 9B, after the light emitting elements LE are attached to the adhesive layer AL, the light emitting elements LE and the adhesive layer AL may be separated from each other, using lase LAS. In an embodiment, a laser lift-off (LLO) process may be performed between the adhesive layer AL and the light emitting elements LE. In embodiments, where the laser LAS is radiated onto the adhesive layer AL, the adhesion of the adhesive layer AL may be decreased.

Referring to FIG. 9C, in a state in which the adhesion between the light emitting elements LE and the adhesive layer AL is decreased as the LLO process is performed, the stamp layer STL and the light emitting elements LE may be attached to each other by relatively stronger adhesion, and therefore, the light emitting elements LE and the adhesive layer AL may be separated from each other.

However, the method in which the adhesive layer AL and the light emitting elements LE are separated from each other using the laser LAS is not limited to the above-described embodiment. In an embodiment, where the laser LAS is radiated onto the adhesive layer AL, a portion of the adhesive layer AL may be removed in an area in which the light emitting elements LE and the adhesive layer AL are adjacent to each other. Accordingly, the light emitting elements LE are separated from the adhesive layer AL to be transferred onto the stamp layer STL.

FIGS. 10A to 10F are conceptual views schematically illustrating operation stages in which the apparatus transfers light emitting elements onto a pixel circuit layer on a circuit board in accordance with an embodiment of the disclosure.

In FIGS. 10A to 10F, the same or like elements of the apparatus 100 as those shown in FIGS. 4, 5A, 5B, 6A to 6D, and 7 are labeled with the same reference characters as used above to describe the embodiment of the apparatus for manufacturing the display device above, and any repetitive detailed description thereof will hereinafter be omitted or simplified.

In addition, in FIGS. 10A to 10F, some components of the pressurizing unit PP, i.e., the driving bracket DB, the driving chamber DC, and a portion of an upper end of the driving shaft DS will be omitted for convenience of illustration. Particularly, for convenience of description, in FIGS. 10B to 10F, the second clamper CLP2 among the first to fourth clampers CLP1 to CLP4 and the second edge area EA2 of the stamp member STM, which is clamped and extended by the second clamper CLP2, will be enlarged and described in detail. That is, descriptions of the first clamper CLP1, and the third clamper CLP3, and the fourth clamper CLP4, the first edge area EA1, the third edge area EA3, and the fourth edge area EA4 of the stamp member STM will be the same as descriptions of the second clamper CLP2 and the second edge area EA2 of the stamp member STM, and any repetitive detailed descriptions thereof will be omitted.

In addition, FIGS. 10A to 10F are views illustrating stages in which the apparatus 100 attaches light emitting elements transferred onto the stamp member STM on a circuit board CB. For convenience of illustration, the light emitting elements LE attached to one surface of the stamp member STM, which faces the circuit board CB, are not shown in the drawings.

FIG. 10A illustrates a state in which the clamping unit is waiting before the clamping unit approaches toward the circuit board in a state in which the clamping unit maintains the clamping posture.

Referring to FIG. 10A, as described with reference to FIG. 8F, as the first to fourth clampers CLP1 to CLP4 are moved in the second direction DR2 by the restoring force of the third elastic member EM3, the adsorption area AA of the stamp member STM may be applied with a tensile force in four different directions on a plane formed by the third direction DR3 and the fourth direction DR4. In this state, the apparatus 100 may be in a waiting state before the apparatus 100 approaches the circuit board CB in a state in which the light emitting elements LE are transferred onto the stamp member STM while going through the stages shown in FIGS. 9A to 9C.

FIG. 10B illustrates a state in which the light emitting elements attached to a bottom surface of the stamp member is in contact with a pixel circuit layer of the circuit board in a state in which the clamping unit maintains the clamping posture.

Referring to FIG. 10B, the driving rod DL may continuously apply a force in the first direction DR1 to the guide member GM in a state in which the light emitting elements LE attached to the bottom surface of the stamp member STM is in contact with a pixel circuit layer (PCL shown in FIG. 3) of the circuit board CB. Until before the first clamping body CLB1 is in contact with the stopper ST, the force with which the driving rod DL applies to the guide member GM may be transferred as a force with which the pressing member PM pressurizes the pressing area PA of the stamp member STM. Accordingly, like the adsorption area AA, the pressing area may also be adhered closely to a top surface of the pixel circuit layer PCL.

FIG. 10C illustrates a state in which the posture of the clamping unit is changed from the clamping posture to the open posture.

Referring to FIG. 10C, in a state in which the clamping unit CLP is in contact with the stopper ST, the driving rod DL may continuously pressurize the guide member GM. As the first clamping body CLB1 is in contact with the stopper ST, the clamping unit CLP may no longer slide in the first direction DR1 even when the driving rod DL pressurizes the guide member GM in the first direction DR1. Accordingly, the force with which the driving rod DL pressurizes the guide member GM may become greater than the compressive force of the first elastic member EM1, such that the force with which the driving rod DL pressurizes the guide member GM in the first direction DR1 may be changed to a force with which the second clamping body CLB2 is rotated with respect to the rotating shaft AX. In an embodiment, for example, the second clamping body CLB2 of the second clamper CLP2 may be rotated clockwise with respect to the rotating shaft AX by the force with which the driving rod DL pressurizes the guide member GM.

As the second clamping body CLB2 is rotated clockwise with respect to the rotating shaft AX, the posture of the clamping unit CLP may be changed from the clamping posture to the open posture. Accordingly, the first inclined surface INS1 of the first clamping body CLB1 and the second inclined surface INS2 of the second clamping body CLB2 may be relatively spaced apart from each other. When the first inclined surface INS1 and the second inclined surface INS2 are spaced apart from each other as described above, the clamping area CA of the stamp member STM may be separated from the second clamping body CLB2 by the restoring force to move toward the circuit board CB at a predetermined distance.

In an embodiment, the pressing member PM may continuously pressurize at least a portion of the pressing area PA of the stamp member STM in the first direction DR1. Accordingly, at least a portion of the pressing area PA may maintain a state in which the at least a portion of the pressing area PA is adhered closely to a side of the circuit board CB.

FIG. 10D illustrates a state in which a portion of the stamp member starts being detached from the stamp head unit.

Referring to FIG. 10D, in a state in which the driving rod DL continuously pressurizes the guide member GM in the first direction DR1, the main body unit MBP may move in the second direction DR2. When the main body unit MBP moves in the second direction DR2 as described above, the stamp head unit SHP may also move together with the main body unit MBP in the second direction DR2. The pressing member PM may be moved at a predetermined distance in the first direction DR1 by the restoring force of the second elastic member EM2, thereby continuously pressurizing the pressing area PA of the stamp member STM.

The stamp member STM may maintain a state in which the stamp member STM is adhered closely to the stamp head unit SHP at an initial stage in which the main body unit MBP moves in the second direction DR2 as the stamp member STM is adsorbed by the stamp head unit SHP. In this state, when the main body unit MBP continuously moves in the second direction DR2, the stamp member STM may be detached from the stamp head unit SHP from an edge portion of the adsorption area AA, which is adjacent to the pressing area PA.

FIG. 10E illustrates a state in which the stamp member is being detached from the stamp head unit.

Referring to FIG. 10E, in a state in which the driving rod DL continuously pressurizes the guide member GM in the first direction DR1, the main body unit MBP may continuously move in the second direction. In other words, as compared with a position of the main body unit MBP shown in FIG. 10D, the main body unit MBP may be further spaced apart from the circuit board CB at a predetermined distance. When the main body unit MBP further moves in the second direction DR2 as described above, the stamp head unit SHP may also be more distant from the circuit board CB. The pressing member PM may maintain a state in which the pressing area PA of the stamp member STM is continuously pressurized in the first direction DR1 by the restoring force of the second elastic member EM2.

As the stamp head unit SHP further moves in the second direction DR2 as described above, the adsorption area AA of the stamp member STM may be gradually detached from the stamp head unit SHP along a direction facing the center of the adsorption area AA from an edge portion adjacent to the pressing area PA. FIG. 10E illustrates a state in which only a central portion of the adsorption area AA maintains a state in which the central portion is adsorbed by the stamp head unit SHP and the other portion of the adsorption area AA is being detached from the stamp head unit SHP.

FIG. 10F illustrates a state in which the stamp member is completely detached from the stamp head unit.

Referring to FIG. 10F, in a state in which the driving rod DL continuously pressurizes the guide member GM in the first direction DR1, the main body unit MBP may further move in the second direction DR2 up to a position at which the pressing member PM is separated from the stamp member STM. The adsorption area AA of the stamp member STM may be completely detached from the stamp head unit SHP, to be adhered closely to the circuit board CB. Although not shown in the drawing, a laser lift-off (LLO) process may be performed on a boundary surface between the stamp member STM and the circuit board CB in this state, such that the light emitting elements LE attached to the stamp member STM can be transferred onto the pixel circuit layer PCL of the circuit board CB.

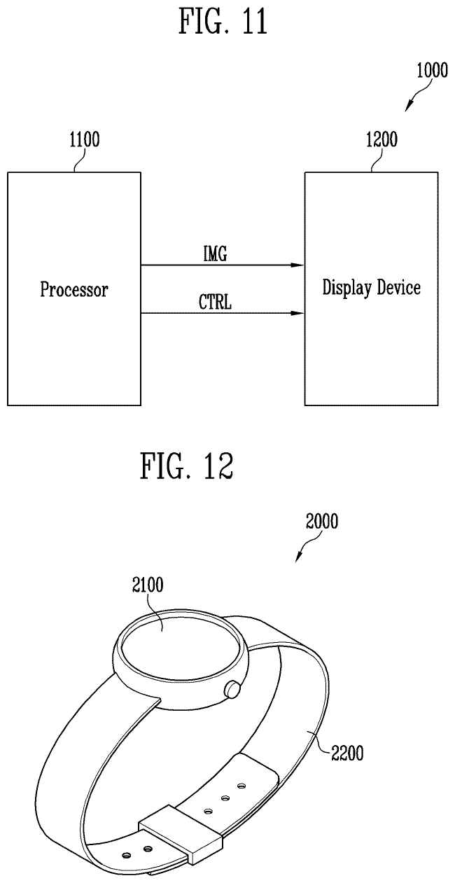

FIG. 11 is a block diagram illustrating an embodiment of a display system.

Referring to FIG. 11, an embodiment of the display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), or the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identically to the display device 10 described with reference to FIG. 1.

The display system 1000 may be or included in a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may be included in a head mounted display (HMD) device, a virtual reality (VR) device, a mixed reality (MR) device, or an augmented reality (AR) device.

FIGS. 12 to 15 are perspective views illustrating application examples of the display system shown in FIG. 11.

Referring to FIG. 12, the display system 1000 shown in FIG. 11 may be applied to a smart watch 2000 including a display part 2100 and a strap part 2200.

The smart watch 2000 may be a wearable electronic device. In an embodiment, for example, the smart watch 2000 may have a structure in which the strap part 2200 is mounted on a wrist of a user. The display system 1000 and/or the display device 1200 may be applied to the display part 2100, so that image data including time information can be provided to the user.

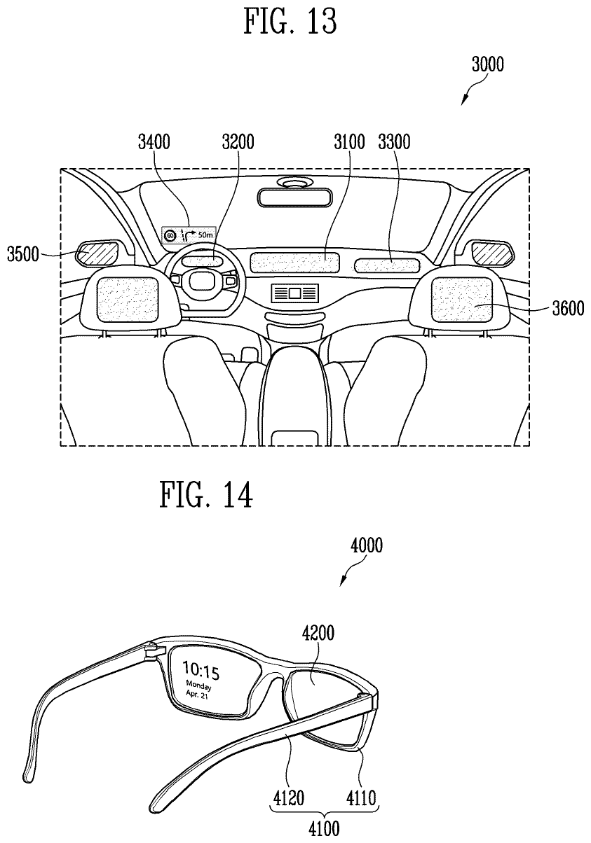

Referring to FIG. 13, the display system 1000 shown in FIG. 11 may be applied to an automotive display system (a display system included in a vehicle) 3000. The automotive display system 3000 may include a computing system provided at the inside/outside of the vehicle to provide image data.

In an embodiment, for example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

Referring to FIG. 14, the display system 1000 shown in FIG. 11 may be applied to smart glasses 4000. The smart glasses 4000 are a wearable electronic device which can be worn on the face of a user. In an embodiment, for example, the smart glasses 4000 may be a wearable device for augmented reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. In addition, a projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In an embodiment, the lens part 4200 may allow an image caused by a light signal transmitted from the projector of the frame 4100 to be reflected by a rear surface (e.g., a surface in a direction facing the eyes of the user) of the lens part 4200 to enable eyes of the user to recognize visual information. In an embodiment, for example, the user may recognize information including time, data, or the like, which are displayed on the lens part 4200. The projector and/or the lens part 4200 may be a kind of display device. The display device 1200 may be applied to the projector and/or the lens part 4200.

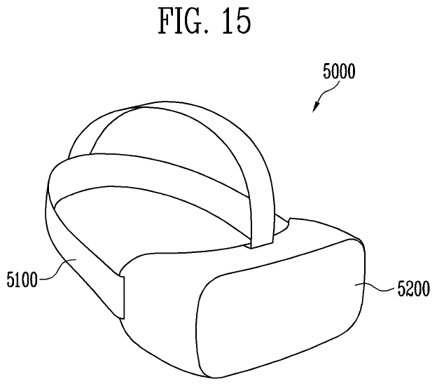

Referring to FIG. 15, the display system 1000 shown in FIG. 11 may be applied to a head mounted display device 5000.

The head mounted display device 5000 may be a wearable electronic device which can be worn on the head of a user. In an embodiment, for example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. In another embodiment, for example, the head mounted band 5100 may be implemented in the form of a glasses frame, a helmet or the like.

The display accommodating case 5200 may accommodate the display system 1000 and/or the display device 1200.

In embodiments of the apparatus for manufacturing the display device in accordance with the disclosure, the transfer reliability of a light emitting element is improved, such that a risk that the light emitting element will not be transferred can be reduced and the yield of the display device can be increased.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, comprising:
a stamp member including an adsorption area and first to fourth edge areas surrounding the adsorption area in different directions;
a stamp head unit which adsorbs the adsorption area of the stamp member;
a main body unit including the stamp head unit installed therein, wherein the main body unit is movable along a first direction facing the stamp member and a second direction opposite to the first direction;
a clamping unit installed in the main body unit to be movable along the first direction and the second direction; and
a pressurizing unit installed in the main body unit to be movable along the first direction and the second direction, wherein the pressurizing unit operates in one of a first mode, in which the clamping unit is not pressurized, and a second mode, in which the clamping unit is pressurized in the first direction,
wherein the clamping unit comprises first to fourth clampers which clamp the first to fourth edge areas of the stamp member, respectively, when the pressurizing unit is changed from the second mode to the first mode.

2. The apparatus of claim 1, wherein each of the first to fourth edge areas includes:
a first non-adsorption area relatively adjacent to the adsorption area; and
a second non-adsorption area relatively more distant from the adsorption area than the first non-adsorption area,
wherein a width of the first non-adsorption area gradually decreases along a direction distant from the adsorption area, and
wherein a width of the second non-adsorption area is constant along the direction distant from the adsorption area.

3. The apparatus of claim 2, wherein the width of the second non-adsorption area is smaller than a width of the adsorption area.

4. The apparatus of claim 1, wherein a width of each of the first to fourth edge areas gradually decreases along a direction distant from the adsorption area.

5. The apparatus of claim 1, wherein each of the first to fourth clampers includes:
a first clamping body installed in the main body unit to be slidable along the first direction and the second direction;
a rotating shaft installed in the first clamping body to be rotatable with respect to a third direction intersecting the first direction;
a second clamping body installed at the rotating shaft to rotatably move with respect to the rotating shaft to be positioned in a clamping posture, at which the stamp member is clamped, or in an open posture, at which the stamp member is not clamped; and
a first elastic member installed between the rotating shaft and the second clamping body, to apply, to the second clamping body, a force with which the second clamping body is adhered closely to the first clamping body.

6. The apparatus of claim 5, wherein the main body unit includes a stopper which limits a movement of the clamping unit in the first direction when the pressurizing unit operates in the second mode,
wherein the second clamping body includes a guide member extending in a radius direction of the rotating shaft, and
wherein the guide member is linearly moved in the first direction by a force applied by the pressurizing unit before the clamping unit is in contact with the stopper when the pressurizing unit operates in the second mode, and is rotatably moved with respect to the rotating shaft by a force applied by the pressurizing unit after the clamping unit is in contact with the stopper.

7. The apparatus of claim 6, wherein the first clamping body includes a first inclined surface on which one surface of a corresponding one of the first to fourth edge areas of the stamp member is settled,
wherein the second clamping body includes a second inclined surface on which an opposite surface of the corresponding one of the first to fourth edge areas of the stamp member is settled,
wherein the clamping posture of the second clamping body is a posture at which the first inclined surface and the second inclined surface are relatively adjacent to each other as the guide member linearly moves, and
wherein the open posture of the second clamping body is a posture at which the first inclined surface and the second inclined surface are relatively spaced apart from each other as the guide member rotatably moves.

8. The apparatus of claim 7, wherein a plurality of bumps which fixes the opposite surface are defined on the second inclined surface.

9. The apparatus of claim 5, wherein the first elastic member includes a torsional spring.

10. The apparatus of claim 1, further comprising a stage spaced apart from the stamp head unit in the first direction, to support at least a portion of the first to fourth edge areas,
wherein the stage includes a groove portion recessed from an upper surface thereof in the first direction, and
wherein the groove portion accommodates the adsorption area of the stamp member when the pressurizing unit operates in the second mode.

11. The apparatus of claim 10, wherein, when a mode of the pressurizing unit is changed from the first mode to the second mode,
the stamp head unit allows the stamp member to enter into the groove portion in a state in which the adsorption area of the stamp member is adsorbed by a force with which the main body unit moves in the first direction.

12. The apparatus of claim 10, wherein each of the first to fourth edge areas includes a pressing area adjacent to the adsorption area and a clamping area except the pressing area,
wherein the clamping unit includes:
a pressing member extending in the first direction;
a guide groove including the pressing member installed therein; and
a second elastic member installed in the guide groove, and
wherein the pressing member pressurizes the pressing area when the pressurizing unit operates in the second mode.

13. The apparatus of claim 12, wherein, when the pressurizing unit operates in the second mode,
the pressing member is moved in the first direction by a force with which the pressurizing unit pressurizes the clamping unit after the stamp member is in contact with a bottom surface of the groove portion, such that the pressing area is pressurized by the pressing member,
the second elastic member is compressed in the second direction by a force with which the pressing member pressurizes the pressing area, to apply a restoring force to the pressing member in the first direction, and
the clamping area of the stamp member receives a repulsive force in the second direction while being in contact with a corner of the groove portion, to be bent.

14. The apparatus of claim 13, wherein, when a mode of the pressurizing unit is changed from the second mode to the first mode,
the adsorption area of the stamp member is in contact with the stamp head unit,
the pressing area of the stamp member is in contact with the pressing member, and
the clamping area of the stamp member is in contact with the clamping unit.

15. The apparatus of claim 14, wherein, after the mode of the pressurizing unit is changed from the second mode to the first mode,
a degree to which one of the clamping areas is bent with respect to the adsorption area is greater than a degree to which a corresponding one of the pressing areas is bent with respect to the adsorption area.

16. The apparatus of claim 14, wherein a position at which the adsorption area and the stamp head unit are in contact with each other is closer to the stage than a position at which one of the pressing areas is in contact with the pressing member.

17. The apparatus of claim 12, wherein the second elastic member includes a compression spring.

18. The apparatus of claim 1, further comprising a third elastic member connected between the main body unit and the clamping unit,
wherein the third elastic member is extended when the pressurizing unit operates in the second mode, to apply a restoring force to the clamping unit in the second direction.

19. The apparatus of claim 18, wherein, when a mode of the pressurizing unit is changed from the first mode to the second mode, the clamping unit is moved in the first direction by a force with which the pressurizing unit pressurizes the clamping unit, and
wherein, when the mode of the pressurizing unit is changed from the second mode to the first mode, the clamping unit is moved in the second direction by the restoring force in a state in which the clamping unit clamps the first to fourth edge areas of the stamp member, such that a tensile force is applied to the adsorption area of the stamp member in different directions.

20. The apparatus of claim 18, wherein the third elastic member includes an extension spring.
